(19) United States
(12) Patent Application Publication
(10) Pub. No.: US 2005/0003310 A1
(43) Pub. Date: Jan. 6, 2005

(54) Etching process including plasma pretreatment for generating fluorine-free carbon-containing polymer on a photoresist pattern

(75) Inventors: Keun-Hee Bai, Yeongtong-gu (KR); Chang-Jin Kang, Suwon-si (KR); Kyeong-Koo Chi, Gangnam-gu (KR); Myeong-Cheol Kim, Suwon-si (KR)

Correspondence Address: Frank Chau, Esq.;F. CHAU & ASSOCIATES, LLP, 1900 Hempstead Turnpike, East Meadow, NY, 11554, US

(73) Assignee: SAMSUNG ELECTRONICS CO., LTD.

(21) Appl. No.: 10/802,150

(22) Filed: Mar. 17, 2004

(30) Foreign Application Priority Data
Jul. 2, 2003 (KR) 2003-44543

(51) Int. Cl. G03F 7/36

(52) U.S. Cl. 430/323; 438/694; 216/62; 216/67; 216/64

(57) ABSTRACT

An etching process including plasma pretreatment for generating a polymer layer formed of carbon on a photoresist pattern. The photoresist pattern is treated with plasma that does not contain fluorine radicals and that provides carbon radicals. An etching process is performed on an etching target layer by using the photoresist pattern as an etch mask.

### BACKGROUND

1. Technical Field of the Invention

The present disclosure relates to an etching process used in the manufacture of semiconductor integrated circuit devices, and more particularly, to an etching process in which a photoresist pattern is treated with plasma to generate a fluorine-free carbon-containing polymer layer on the photoresist pattern before etching an etching target layer to suppress deformation of the photoresist pattern.

2. Discussion of Related Art

In recent years, as semiconductor integrated circuit devices have become highly integrated, the design rule has been reduced to 90 nm or lower. Conventionally, to manufacture highly integrated circuits, fine patterns are formed by patterning contact holes with a very large depth or lines with a very fine linewidth.

This patterning process is performed by a selective etching process, in which a photoresist pattern obtained by a photolithography process is used as an etch mask. The photolithography process should be performed using light having a wavelength band of 192 nm to accommodate the sub-90-nm design rules. Thus, an ArF light source is used to provide light having a wavelength band of 192 nm.

A photolithography process using the ArF light source (i.e., an ArF photolithography process) is performed using a photoresist material that can be exposed by the ArF light source. This photoresist material may be referred to as an “ArF photoresist material,” to distinguish it from other photoresist materials that are used in other wavelength bands.

The ArF photoresist material is typically less durable than conventional KrF photoresist materials. For example, when a photoresist pattern formed of the ArF photoresist material is used as an etch mask, it may be seriously deformed (e.g., striation or wiggling) during an etching process.

If the photoresist pattern is deformed during the etching process, a pattern formed by the etching process tends to deviate from a desired pattern. In other words, the deformation of the photoresist pattern results in pattern failures.

To overcome pattern failures caused by the deformation of photoresist patterns, a hard mask formed of polysilicon or silicon nitride (Si₃N₄) is conventionally used. However, additional process steps are required to form a hard mask. For example, processes such as deposition of a hard mask, etching of the hard mask, removal of the hard mask, and a cleaning process may be additionally performed. In a semiconductor device manufacturing process, the addition of several process steps leads to an increase in the unit cost of production, thereby impeding the mass production.

Therefore, there is much ongoing research for reinforcing the durability of an ArF light source photoresist pattern during an etching process. For example, methods of irradiating ultraviolet rays (UV) or depositing silicon on a photoresist pattern have been proposed.

However, the UV irradiation process involves the shrinking of photoresist patterns and requires additional equipment. Also, silicon deposition on photoresist patterns hinders removal of the photoresist patterns by ashing after an etching process.

In addition to the foregoing methods, U.S. Patent Publication No. 6,326,307 B1 entitled “Plasma Pretreatment of Photoresist Pattern in an Oxide Etch Process” by Lindley et al. discloses a method of reinforcing the durability of a photoresist pattern by sputtering using argon plasma or by pretreatment using fluoromethane plasma.

However, there is a need for more effective and easier methods of suppressing the deformation of a photoresist pattern.

### SUMMARY OF THE INVENTION

An etching method according to an embodiment of the invention includes preparing a photoresist pattern, treating the photoresist pattern with fluorine-free plasma that provides carbon radicals, and selectively etching an etching target layer by using the plasma-treated photoresist pattern as an etch mask.

An etching method according to another embodiment of the invention includes preparing a photoresist pattern, treating the photoresist pattern with plasma generated by exciting a fluorine-free carbon-containing gas, and selectively etching an etching target layer by using the plasma-treated photoresist pattern as an etch mask.

An etching method according to another embodiment of the invention includes preparing a photoresist pattern, forming a polymer layer including carbon on the photoresist pattern using plasma generated by exciting a fluorine-free carbon-containing gas, and selectively etching an etching target layer by using as an etch mask the photoresist pattern on which the polymer layer is formed.

An etching method according to another embodiment of the invention includes preparing a photoresist pattern by optical photolithography using an ArF light source, treating the photoresist pattern with plasma generated by exciting a fluorine-free carbon-containing gas, selectively etching an etching target layer by using the plasma-treated photoresist pattern as an etch mask, and removing the remaining photoresist pattern by ashing.

The plasma may be generated by exciting carbon monoxide (CO) or carbon dioxide (CO₂).

Also, the etching target layer may be formed of a material layer selected from a group consisting of a silicon oxide layer, a silicon nitride layer, a silicon oxynitride layer, and an organic anti-reflective coating (ARC) layer.

The etching process may be performed using plasma containing fluorine radicals. The etching process may be performed using plasma generated by exciting a fluorocarbon gas.

The etching process may be performed in the same reaction chamber as the plasma treatment without breaking vacuum. The etching process may be performed by applying a radio frequency (RF) bias power to the rear surface of the etching target layer. The plasma treatment may be performed by applying no RF bias power or a lower RF bias power than the RF bias power applied to the etching target layer.

According to various exemplary embodiments of the present invention, an ArF light source photoresist pattern is not eaten away during an etching process so as to minimize pattern failures.

### BRIEF DESCRIPTION OF THE DRAWINGS

The present invention will become readily apparent by reference to the following detailed description when considered in conjunction with the accompanying drawings wherein:

FIG. 1 is a process flowchart illustrating an etching process including plasma pretreatment for generating a fluorine-free carbon-containing polymer layer on a photoresist pattern according to an exemplary embodiment of the present invention;

FIGS. 2 through 7 are cross-sectional views illustrating an etching process according to an exemplary embodiment of the present invention; and

FIGS. 8A through 8C are scanning electron microscope (SEM) photographs illustrating the effect of exemplary embodiments of the present invention.

### DETAILED DESCRIPTION OF THE INVENTION

The present invention will now be described more fully with reference to the accompanying drawings, in which an exemplary embodiment of the invention is shown. This invention may, however, be embodied in many different forms and should not be construed as being limited to the embodiment set forth herein. Rather, the embodiment is provided so that this disclosure is thorough and complete and fully conveys the concept of the invention to those skilled in the art.

In various exemplary embodiments of the present invention, before an etching process is performed on an etching target layer, pretreatment using CO plasma is performed on the surface of a photoresist pattern, such that the photoresist pattern is protected from deformations, such as striation or wiggling, which may propagate from the photoresist pattern to a pattern formed by the etching process to cause pattern failures.

The pretreatment of the photoresist pattern using CO plasma results in a polymer layer that is substantially formed of carbon (C) formed on the photoresist pattern. The polymer layer, esp., a portion of the polymer layer formed on the sidewalls of the photoresist pattern, suppresses the deformation of the photoresist pattern while the etching target layer is being etched, so that the resulting pattern in the etching target layer does not deviate from a desired pattern.

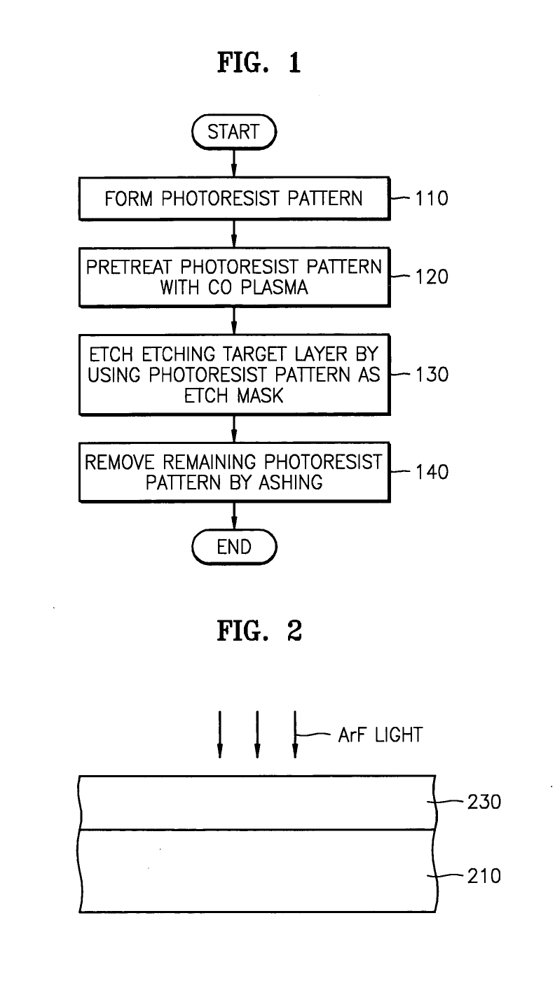

FIG. 1 is a process flowchart illustrating an etching process including plasma pretreatment for generating a fluorine-free carbon-containing polymer layer on a photoresist pattern according to an embodiment of the present invention. Referring to FIG. 1, the etching process includes (110) forming a photoresist pattern by optical lithography, (120) pretreating the photoresist pattern using CO plasma, (130) etching and patterning an etching target layer using the photoresist pattern as an etch mask, and (140) removing the remaining photoresist pattern by ashing. Thus, the resultant pattern is formed.

In step (130), the etching target layer may be, for example, a silicon oxide (SiO₂) layer, a silicon nitride (Si₃N₄) layer, a silicon oxynitride (SiON) layer, or an organic anti-reflective coating (ARC) layer. The resultant pattern may be a line and space pattern or a pattern with contact holes.

The optical lithography used to form the photoresist pattern may be performed using ArF light having a wavelength band of 192 nm for sub-90-nm design rules. Since ArF light is used for the optical lithography, the photoresist pattern may be formed of a photoresist material that reacts to the ArF light, i.e., an ArF photoresist material.

It is known that the ArF photoresist material may be easily eaten away by an etchant (e.g., fluorocarbon plasma) that is used to etch the etching target layer. Generally, fluorocarbon gases, such as CHₓF_{y} and CₓF_{y}, are used to etch silicon oxides.

This fluorocarbon gas includes carbon-fluorine bonds. Thus, when the fluorocarbon gas is excited to generate plasma, carbon radicals and fluorine radicals are generated and react so as to etch the etching target layer (e.g., a silicon oxide layer). The fluorine radicals may eat away the photoresist pattern formed of the ArF photoresist material, thereby causing pattern failures.

In the present embodiment of the invention, prior to a main etching process using fluorocarbon plasma, plasma pretreatment is performed on the photoresist pattern to prevent the deformation of the photoresist pattern formed of the ArF photoresist material.

The plasma pretreatment may be performed using a gas that provides carbon (C). That is, the plasma pretreatment using carbon radicals may be performed such that the carbon radicals generate a polymer layer on the photoresist pattern. The gas may contain carbon that provides carbon radicals. A fluorine-free carbon-containing gas is preferred as the gas that provides carbon. For example, CO or CO₂ that includes carbon-oxygen bonds may be used as the gas that provides carbon.

If the gas that provides carbon contains fluorine and is excited to generate plasma, not only carbon radicals but also fluorine radicals are generated. Thus, a polymer layer formed on the photoresist pattern contains fluorine. As a result, fluorine radicals generated in a subsequent etching process may eat away the photoresist pattern through the medium of the fluorine contained in the polymer layer. Accordingly, a fluorine-free gas that provides carbon may be excited to generate plasma in various exemplary embodiments of the present invention.

As described above, the polymer layer, which is formed on the photoresist pattern by the plasma generated by exciting a fluorine-free carbon-containing gas, is formed substantially of carbon (C). This carbon polymer layer, esp., a portion of the carbon polymer layer that covers the sidewalls of the photoresist pattern, protects the photoresist pattern from deformation, such as striation or wiggling, during a subsequent etching process and prevents the deformation from propagating to patterns obtained by etching the etching target layer.

Most of the oxygen radicals, which are generated when the carbon-containing gas is excited to generate plasma, are exhausted from the reaction chamber.

After the etching target layer is etched, the remaining photoresist pattern is removed by ashing, such as, for example, ashing using a gas containing an O₂ gas or a N₂ gas. During the ashing, the polymer layer formed of carbon is removed together with the photoresist pattern.

Hereinafter, an etching process according to an exemplary embodiment of the invention including a plasma pretreatment for generating a fluorine-free carbon-containing polymer layer on a photoresist pattern will be described with reference to FIGS. 2 through 6.

Referring to FIG. 2, a photoresist layer 230 is formed on an etching target layer 210 and exposed by optical lithography. The etching target layer 210 may be a silicon oxide (SiO₂) layer, a silicon nitride (Si₃N₄) layer, a silicon oxynitride (SiON) layer, or an organic anti-reflective coating (ARC) layer. The photoresist layer 230 is formed on the etching target layer 210. An anti-reflective coating (ARC) layer may be further formed between the photoresist layer 230 and the etching target layer 210.

After the photoresist layer 230 is formed, the photoresist layer 230 is patterned by optical lithography. The patterning process may be performed using an ArF light source to accommodate the linewidth of a pattern that will be formed by the patterning of the etching target layer 210 or the design rule. The ArF light source provides light having a wavelength band of about 192 nm, which is necessarily required for sub-90-nm design rules.

Since the ArF light source is used for patterning the photoresist layer 230, the photoresist layer 230 may be formed of an ArF photoresist material that is appropriate for the ArF light source. A KrF photoresist material or a deep ultra violet (DUV) photoresist material is not appropriate for the ArF light source.

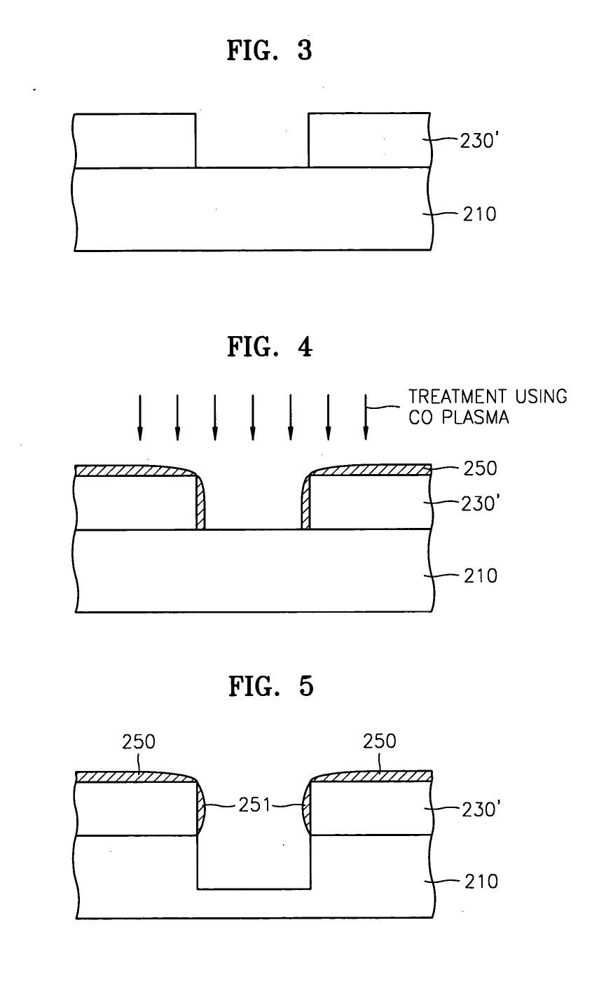

FIG. 3 illustrates the formation of a photoresist pattern 230′. Referring to FIG. 3, the surface of the photoresist pattern 230′ is treated with carbon plasma to form a polymer layer 250 on the photoresist pattern 230′. As described above, the carbon plasma may be generated by exciting a fluorine-free gas that provides carbon, e.g., carbon monoxide (CO) or carbon dioxide (CO₂).

The polymer layer 250 is substantially formed of carbon. Thus, the treatment using carbon plasma may be understood as a method of depositing carbon on the photoresist pattern 250. The polymer layer 250 preferably does not contain an element such as fluorine that may eat away the photoresist pattern 230′. Accordingly, the polymer layer 250 can protect the photoresist pattern 230′ more effectively.

As described above, if the polymer layer 230′ contains fluorine, the fluorine may be a path or a medium that allows fluorine plasma or fluorine radicals, which are used in etching the etching target layer, to eat away the photoresist pattern 230′. However, in the present embodiment of the invention, the polymer layer 250 is formed of CO plasma and does not contain fluorine. Thus, the polymer layer 250 is mainly formed of fluorine-free carbon so that it can protect the photoresist pattern 230′ more effectively.

In addition to the polymer layer 250, a carbon layer may be deposited on the surface of the etching target layer 210 which is exposed by the photoresist pattern 230′ due to a carbon plasma reaction. However, the carbon layer does not substantially affect a subsequent etching process. Generally, the etching process for patterning the etching target layer 210 may be performed using fluorocarbon plasma as an etchant as well as argon plasma. The carbon layer may be easily broken due to the ion bombardment of the argon plasma so as not to have any substantial affect on the etching process.

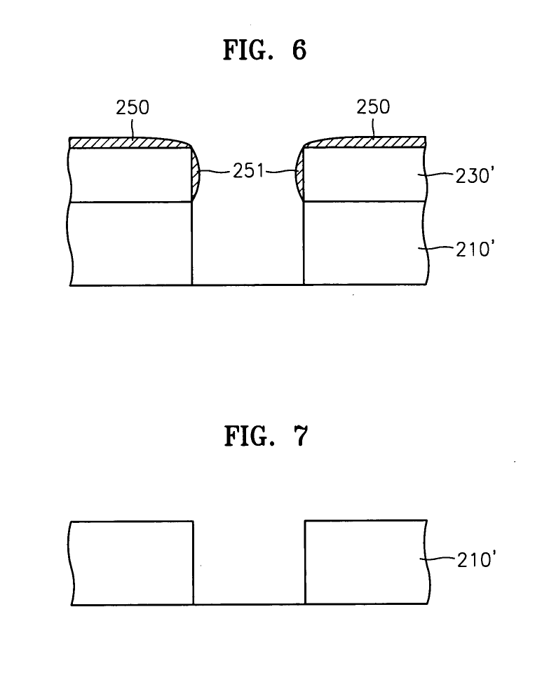

FIG. 5 illustrates the selective etching of the etching target layer 210. Referring to FIG. 5, an exposed portion of the etching target layer 210 is selectively etched by using the photoresist pattern 230′ as an etch mask. The etching process may be performed by using plasma or by applying a radio frequency (RF) bias power to the rear surface of a wafer where the etching target layer 210 is formed so as to improve the etching characteristic.

An etchant used in the etching process may contain a fluorocarbon gas, for example, ChₓF_{y} or CₓF_{y}, which is excited to generate plasma. In addition to the fluorocarbon gas, an argon gas may be contained in the etchant and excited to generate plasma. The argon gas is used to facilitate the etching reaction.

In the etching process, the plasma provides fluorine radicals to the etching target layer 210 formed of, for example, silicon oxide, such that the fluorine radicals react on the silicon oxide, thus generating volatile reactant. The fluorine radicals react on the silicon oxide to displace oxygen of the silicon oxide, and oxygen radicals generated by the displacement react on the fluorine radicals as well as carbon radicals and are converted into carbon monoxide or carbon dioxide and then exhausted.

A portion of the photoresist pattern 230′ also may be etched when the etching target layer 210 is etched. However, the carbon polymer layer 250 formed on the photoresist pattern 230′ prevents penetration of the fluorine radicals into the photoresist pattern 230′ or reaction of the fluorine radicals on the photoresist pattern 230′. In particular, a portion 251 of the polymer layer 250 that covers the sidewalls of the photoresist pattern 230′ prevents penetration of the fluorine radicals into the sidewalls of the photoresist pattern 230′, so as to prevent the sidewalls of the photoresist pattern 230′ from deforming.

The polymer layer 250 may be partially removed during the etching process, and a portion of the polymer layer 250, which is formed on the top surface of the photoresist pattern 230′, may be thinned out as the photoresist pattern 230′ is being etched. However, the portion 251 of the carbon polymer layer 250 effectively protects the sidewalls of the photoresist pattern 230′ from the plasma including fluorine radicals used to etch the etching target layer 210. Further, while the etching process is being performed, the generated polymer layer 250 can protect the sidewalls of the photoresist pattern 230′ more effectively. Thus, deformation of the sidewalls of the photoresist pattern 230′ can be prevented.

The etching of the etching target layer 210 may be performed in situ along with the forming of the polymer layer 250. In other words, the pretreatment using the carbon plasma may be performed in the same reaction chamber as the etching of the etching target layer 210 without breaking vacuum.

Application of RF bias power into the rear surface of the wafer may be omitted when the carbon plasma is being generated by excitement of CO gas. This is because the RF bias power may impede the generation of the polymer layer 250 formed of carbon using the carbon plasma. Alternatively, during the plasma pretreatment using CO plasma, a much lower RF bias power may be applied than the RF bias power applied during etching of the etching target layer 210. For example, whereas an RF bias power of about 1500 W may be applied when etching the etching target layer 210, a low RF bias power of about 400 W may be applied during the pretreatment using CO plasma.

When the plasma pretreatment and the etching process are performed in situ, the plasma pretreatment may be performed for about 2 minutes. Since the thickness of the resultant polymer layer 250 depends on the duration of the plasma pretreatment, the time may vary according to the desired process results.

When the RF bias power is applied to the rear surface of the wafer during the plasma pretreatment, the RF bias power should be controlled according to the duration of the plasma pretreatment. That is, during the plasma pretreatment, the application of the RF bias power may be omitted or a very low RF bias power may be applied. In subsequent etching of the etching target layer 210, the RF bias power is raised to an appropriate level and applied.

FIG. 6 illustrates the formation of an etching target pattern 210′. Referring to FIG. 6, as described with reference to FIG. 5, the exposed portion of the etching target layer 210 is etched to form the etching target pattern 210′. The etching target pattern 210′ may be a line and space pattern or a pattern with contact holes, which is appropriate for the manufacture of semiconductor integrated circuit devices.

FIG. 7 illustrates the removal of the remaining photoresist pattern 230′. Referring to FIG. 7, the remaining photoresist pattern 230′ is removed by ashing. This ashing process may use an O₂ gas or a N₂ gas. As described above, since the polymer layer 250 is mostly formed of carbon, it is removed during the ashing process and does not remain on the etching target pattern 210′.

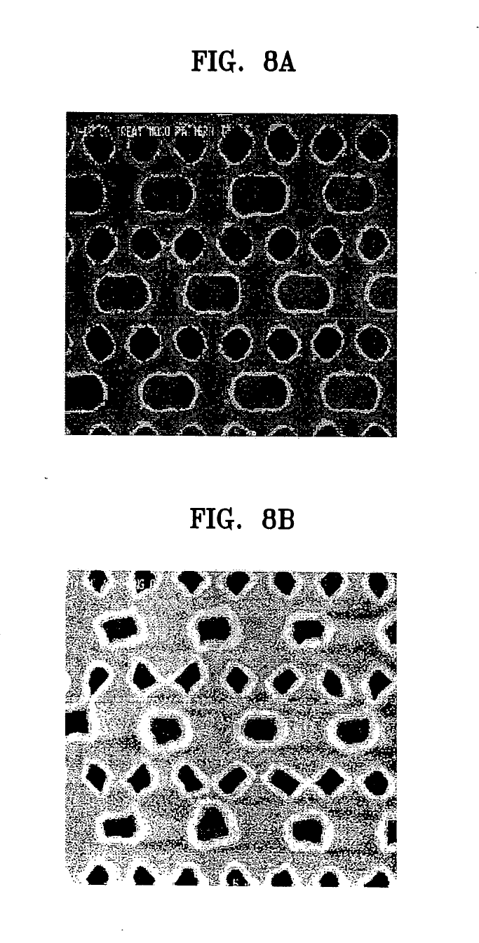

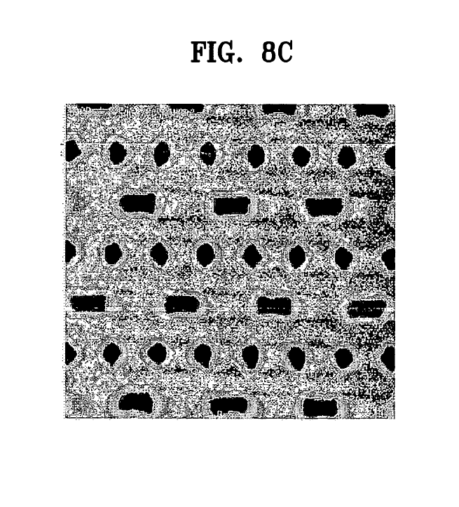

FIGS. 8A through 8C are SEM photographs illustrating the effect of an etching process according to an exemplary embodiment of the present invention.

FIG. 8A illustrates a photoresist pattern formed by optical lithography. FIG. 8B illustrates an etching target layer (i.e., a silicon oxide layer) patterned by using the photoresist pattern as an etch mask without performing pretreatment using CO plasma. Also, FIG. 8C illustrates an etching target pattern formed by performing an etching process on an etching target layer (i.e., a silicon oxide layer) after pretreating the photoresist pattern using CO plasma.

Referring to FIGS. 8A, 8B, and 8C, FIG. 8C shows that when the etching process includes the pretreatment using CO plasma according to the present invention, the deformations of the etching target pattern caused by the etching process are effectively prevented.

As explained thus far, when an etching target layer is selectively etched by using a photoresist pattern formed of an ArF photoresist material as an etch mask, pretreatment using CO plasma is further performed so as to reinforce the durability of the photoresist pattern. The pretreatment using CO plasma generates a polymer layer formed of carbon on the surface of the photoresist pattern, and the polymer layer can prevent etchants from eating away and deforming the photoresist pattern.

In particular, even if an etchant contains fluorine radicals, since the polymer layer is a fluorine-free carbon polymer layer, the deformation of the sidewalls of the photoresist pattern due to the fluorine radicals can be effectively prevented.

Thus, even for the sub-90-nm design rules, it is possible to etch the etching target layer using only the photoresist pattern as an etch mask without any additional hard mask. In exemplary embodiments of the present invention, since deformation of the photoresist pattern can be prevented, an etching target pattern (e.g., a silicon oxide pattern) can be formed to a desired shape.

Also, the pretreatment using CO plasma can be performed in the same reaction chamber as the etching process, i.e., in situ, without any additional apparatus. Further, the polymer layer formed of carbon is removed along with the remaining photoresist pattern by ashing.

While the present invention has been particularly shown and described with reference to preferred embodiments thereof, it will be understood by those of ordinary skill in the art that various changes in form and details may be made therein without departing from the spirit and scope of the present invention as defined by the following claims.

1. An etching method comprising:
preparing a photoresist pattern;
treating the photoresist pattern with plasma that provides carbon radicals; and
selectively etching an etching target layer by using the plasma-treated photoresist pattern as an etch mask.

2. The method of claim 1, further comprising generating the plasma by exciting carbon monoxide.

3. The method of claim 1, further comprising generating the plasma by exciting carbon dioxide.

4. The method of claim 1, wherein the etching target layer is formed of a material layer selected from a group consisting of a silicon oxide layer, a silicon nitride layer, a silicon oxynitride layer, and an organic anti-reflective coating layer.

5. The method of claim 1, wherein the etching of the etching target layer is performed using plasma containing fluorine radicals.

6. The method of claim 1, wherein the etching of the etching target layer is performed using plasma generated by exciting a fluorocarbon gas.

7. The method of claim 1, wherein the etching of the etching target layer is performed in a same reaction chamber as the plasma treatment without breaking vacuum.

8. The method of claim 7, wherein the etching of the etching target layer is performed by applying an RF bias power to a rear surface of the etching target layer,
and the plasma treatment is performed by applying no RF bias power or applying a lower RF bias power than the RF bias power applied during the etching of the etching target layer.

9. An etching method comprising:
preparing a photoresist pattern;
treating the photoresist pattern with plasma generated by exciting a fluorine-free carbon-containing gas; and
selectively etching an etching target layer by using the plasma-treated photoresist pattern as an etch mask.

10. The method of claim 9, further comprising generating the plasma by exciting carbon monoxide.

11. The method of claim 9, further comprising generating the plasma by exciting carbon dioxide.

12. An etching method comprising:
preparing a photoresist pattern;
forming a polymer layer comprising carbon on the surface of the photoresist pattern using plasma generated by exciting a fluorine-free carbon-containing gas; and
selectively etching an etching target layer using as an etch mask the photoresist pattern on which the polymer layer is formed.

13. The method of claim 12, wherein the plasma is generated by exciting carbon monoxide.

14. The method of claim 12, wherein the plasma is generated by exciting carbon dioxide.

15. An etching method comprising:
preparing a photoresist pattern by optical lithography using an ArF light source;
treating the photoresist pattern with plasma generated by exciting a fluorine-free carbon-containing gas;
selectively etching an etching target layer by using the plasma-treated photoresist pattern as an etch mask; and
removing the remaining photoresist pattern by ashing.

16. The method of claim 15, wherein the plasma is generated by exciting carbon monoxide.

17. The method of claim 15, wherein the etching target layer is formed of a material layer selected from a group consisting of a silicon oxide layer, a silicon nitride layer, a silicon oxynitride layer, and an organic anti-reflective coating layer.

18. The method of claim 15, wherein the etching of the etching target layer is performed using plasma generated by exciting a fluorocarbon gas.

19. The method of claim 15, wherein the etching of the etching target layer is performed in a same reaction chamber as the plasma treatment without breaking vacuum.

20. The method of claim 19, wherein the etching of the etching target layer is performed by applying an RF bias power to a rear surface of the etching target layer,
and the plasma treatment is performed by applying no RF bias power or applying a lower RF bias power than the RF bias power applied during the etching of the etching target layer.

21. An etching method comprising:
preparing a photoresist pattern;
forming a polymer layer comprising carbon on the surface of the photoresist pattern; and
selectively etching an etching target layer by using the photoresist pattern on which the polymer layer is formed as an etch mask.

22. The method of claim 21, wherein the polymer layer is formed using plasma generated by exciting a fluorine-free carbon-containing gas.

23. The method of claim 22, further comprising generating the plasma by exciting carbon monoxide.

24. The method of claim 22, further comprising generating the plasma by exciting carbon dioxide.

25. The method of claim 21, wherein the etching of the etching target layer is performed using plasma generated by exciting a fluorocarbon gas.
